(19) United States
(12) Patent Application Publication
(10) Pub. No.: US 2024/0203939 A1
(43) Pub. Date: Jun. 20, 2024

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Hyunsoo CHUNG, Suwon-si (KR); Dae-Woo KIM, Suwon-si (KR); Won-Young KIM, Suwon-si (KR)

(21) Appl. No.: 18/219,394

(22) Filed: Jul. 7, 2023

(30) Foreign Application Priority Data
Dec. 19, 2022 (KR) 10-2022-0178439

(51) Int. Cl. H01L 25/065; H01L 23/00; H01L 23/48; H01L 23/538; H01L 25/00

(52) U.S. Cl. CPC H01L 25/0652; H01L 23/481; H01L 23/5383; H01L 24/08; H01L 24/80; H01L 25/50; H01L 24/32; H01L 2224/08146; H01L 2224/32145; H01L 2224/80001

(57) ABSTRACT

A semiconductor package includes a power delivery network, a semiconductor chip on a top surface of the power delivery network, and having first and second surfaces opposite to each other, a second semiconductor chip on the top surface horizontally spaced from the first semiconductor chip, the second semiconductor chip having third surface and fourth surfaces, opposite to each other, chip stacks on the first semiconductor chip, and on the second semiconductor chip. The first surface is an active surface. The third surface is an active surface of the second semiconductor chip. The first chip stack includes third semiconductor chips on the first surface of the first semiconductor chip. The third semiconductor chips is disposed such that an active surface thereof faces the first semiconductor chip, and the first chip stack and the second semiconductor chip may be electrically connected to each other through the power delivery network.

### CROSS-REFERENCE TO RELATED APPLICATIONS

This U.S. non-provisional patent application claims priority under 35 U.S.C. § 119 to Korean Patent Application No. 10-2022-0178439, filed on Dec. 19, 2022, in the Korean Intellectual Property Office, the entire contents of which are hereby incorporated by reference.

### BACKGROUND

### 1. Field

The present disclosure relates to a semiconductor package and a method of fabricating the same, and in particular, to a stack-type semiconductor package that includes a substrate and a plurality of semiconductor chips stacked thereon, and a method of fabricating the same.

### 2. Description of the Related Art

With the recent advances in the electronics industry, demand for high-performance, high-speed, and compact electronic components is increasing. To meet this demand, packaging technologies for mounting a plurality of semiconductor chips in a single package are being developed.

Recently, demand for portable electronic devices has been increasing rapidly in the market, and thus, it is desirable to reduce sizes and weights of electronic components constituting the portable electronic devices. For this, it is desirable to develop packaging technologies for reducing a size and weight of each component and for integrating a plurality of individual components in a single package. Here, a plurality of adhesive members has been used to attach the individual components to each other. However, as the number of adhesive members increases, various technical issues have arisen.

### SUMMARY

An embodiment provides a semiconductor package with improved stability and improved performance, and a method of fabricating the same.

An embodiment provides a semiconductor package with improved performance and a method of fabricating the same.

According to an embodiment, a semiconductor package may include a power delivery network, a first semiconductor chip disposed on a top surface of the power delivery network, the first semiconductor chip having a first surface and a second surface, which are opposite to each other, a second semiconductor chip disposed on the top surface of the power delivery network and horizontally spaced apart from the first semiconductor chip, the second semiconductor chip having a third surface and a fourth surface, which are opposite to each other, a first chip stack disposed on the first surface of the first semiconductor chip, and a second chip stack disposed on the third surface of the second semiconductor chip. The first surface of the first semiconductor chip may be an active surface of the first semiconductor chip, and the third surface of the second semiconductor chip may be an active surface of the second semiconductor chip. The first chip stack may include third semiconductor chips stacked on the first surface of the first semiconductor chip. Each of the third semiconductor chips may be disposed such that an active surface thereof faces the first semiconductor chip, and the first chip stack and the second semiconductor chip may be electrically connected to each other through the power delivery network.

According to an embodiment, a semiconductor package may include a first semiconductor chip having a first surface and a second surface, which are opposite to each other, the first surface being an active surface of the first semiconductor chip, a second semiconductor chip that is horizontally spaced apart from the first semiconductor chip, the second semiconductor chip having a third surface and a fourth surface, which are opposite to each other, the third surface being an active surface of the second semiconductor chip, a power delivery network in direct contact with the second surface of the first semiconductor chip and the fourth surface of the second semiconductor chip, third semiconductor chips vertically stacked on the first surface of the first semiconductor chip, dummy chips disposed on the third surface of the second semiconductor chip, and a silicon substrate disposed on the third semiconductor chips and the dummy chips. The first semiconductor chip may include a first via penetrating the first semiconductor chip, and the second semiconductor chip may include a second via penetrating the second semiconductor chip. The power delivery network may include conductive interconnection lines and an interconnection insulating layer. Each of the first and second vias may be in direct contact with a corresponding one of the conductive interconnection lines. Each of the third semiconductor chips may be disposed such that an active surface of each of the third semiconductor chips faces the first semiconductor chip. The third semiconductor chips may be electrically connected to the second semiconductor chip through the power delivery network.

According to an embodiment, a method of fabricating a semiconductor package may include preparing a silicon substrate, forming a first chip stack and a second chip stack on the silicon substrate, bonding a first semiconductor chip to the first chip stack, bonding a second semiconductor chip to the second chip stack, and forming a power delivery network on the first and second semiconductor chips. The first chip stack may include third semiconductor chips. A top surface of each of the third semiconductor chips may be an active surface. An active surface of the first semiconductor chip may be in contact with the first chip stack, and an active surface of the second semiconductor chip may be in contact with the second chip stack. The third semiconductor chips may be electrically connected to the second semiconductor chip through the power delivery network.

### BRIEF DESCRIPTION OF THE DRAWINGS

Features will become apparent to those of skill in the art by describing in detail exemplary embodiments with reference to the attached drawings in which:

FIG. 1 is a plan view illustrating a semiconductor package according to an embodiment.

FIG. 2 is a sectional view taken along a line I-I′ of FIG. 1 to illustrate a semiconductor package according to an embodiment.

FIG. 3 is an enlarged sectional view illustrating a portion ‘A’ of FIG. 2.

FIG. 4 is an enlarged sectional view illustrating a portion ‘B’ of FIG. 2.

FIG. 5 is an enlarged sectional view illustrating a portion ‘C’ of FIG. 2.

FIG. 6 is an enlarged sectional view illustrating a portion ‘D’ of FIG. 2.

FIGS. 7 to 12 are sectional views, which are taken along the line I-I′ of FIG. 1 to illustrate a method of fabricating a semiconductor package.

### DETAILED DESCRIPTION

Example embodiments will now be described more fully with reference to the accompanying drawings, in which example embodiments are shown.

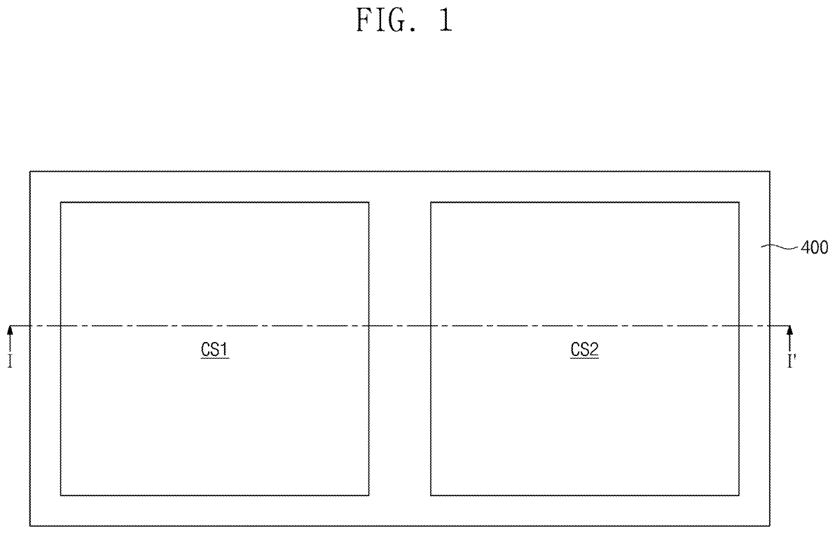

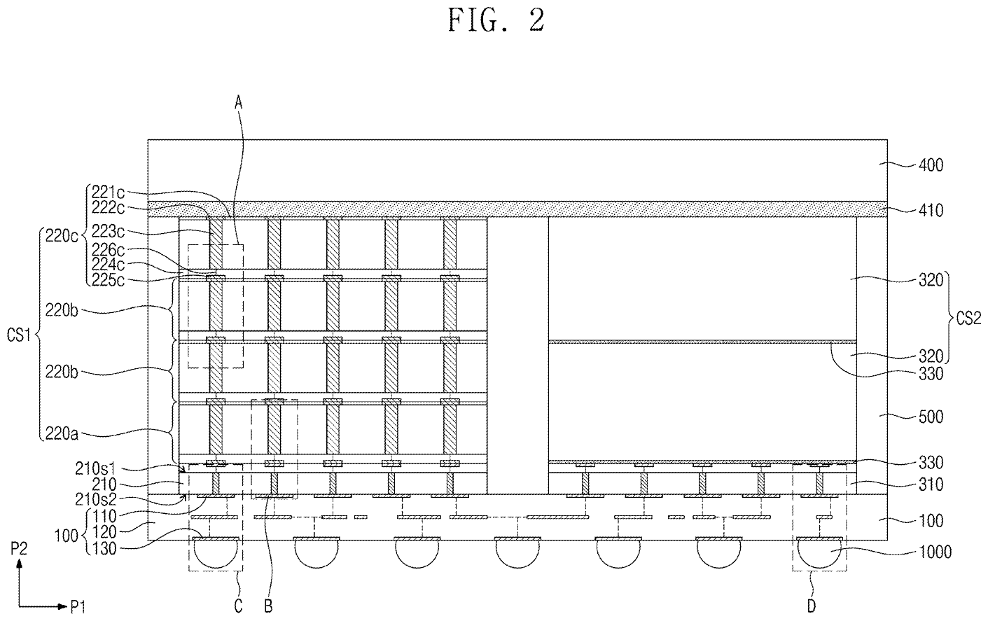

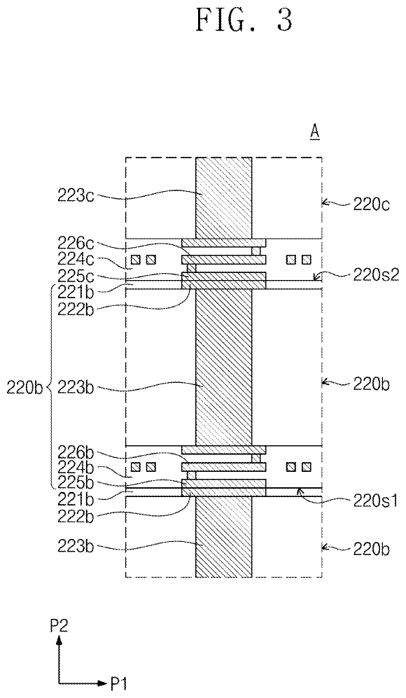

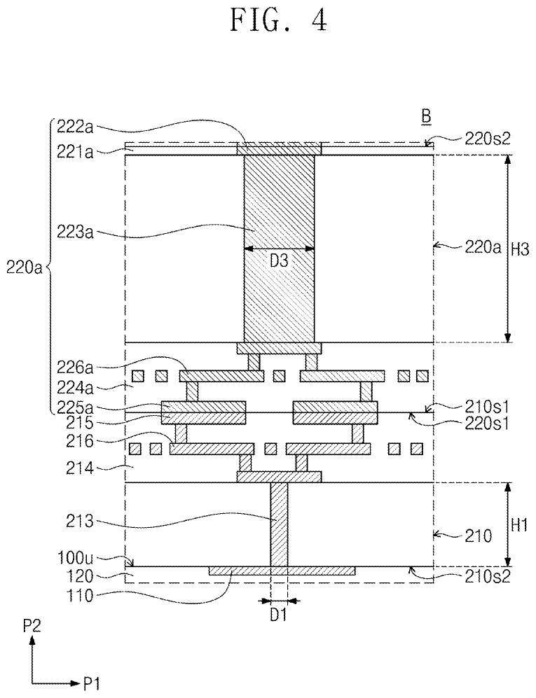

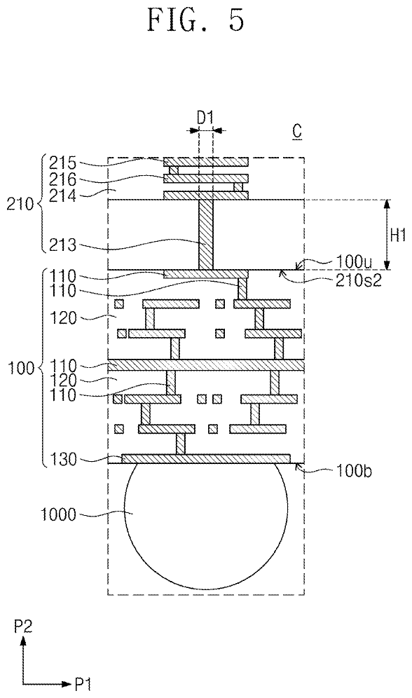

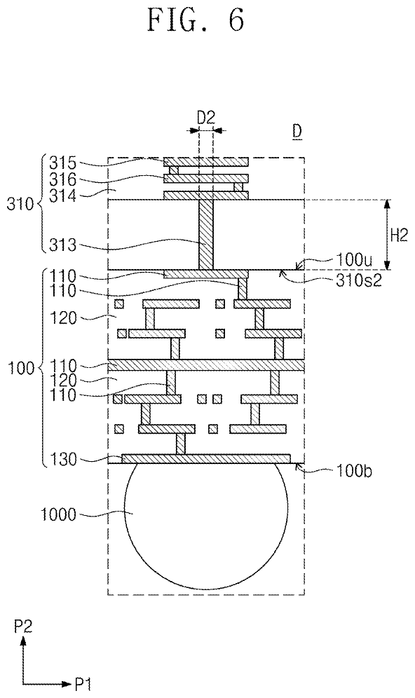

FIG. 1 is a plan view illustrating a semiconductor package according to an embodiment. FIG. 2 is a sectional view taken along a line I-I′ of FIG. 1 to illustrate a semiconductor package according to an embodiment. FIG. 3 is an enlarged sectional view illustrating a portion ‘A’ of FIG. 2. FIG. 4 is an enlarged sectional view illustrating a portion ‘B’ of FIG. 2. FIG. 5 is an enlarged sectional view illustrating a portion ‘C’ of FIG. 2. FIG. 6 is an enlarged sectional view illustrating a portion ‘D’ of FIG. 2.

Referring to FIGS. 1, 2, and 5, a power delivery network 100 may be provided. The power delivery network 100 may include conductive interconnection lines 110, an interconnection insulating layer 120, and outer pads 130. The conductive interconnection lines 110 and the outer pads 130 may be disposed in the interconnection insulating layer 120. The outer pads 130 may be located on a bottom surface 100b of the power delivery network 100. Bottom surfaces of the outer pads 130 may not be covered with the interconnection insulating layer 120. The interconnection insulating layer 120 may expose the bottom surfaces of the outer pads 130.

The conductive interconnection lines 110 may be connected to a corresponding one of the outer pads 130. Some of the conductive interconnection lines 110 may be placed near a top surface 100u of the power delivery network 100. Such conductive interconnection lines 110 may not be fully covered with the interconnection insulating layer 120. Such conductive interconnection lines 110 may be exposed to the outside of the interconnection insulating layer 120. A thickness T1 of each of the conductive interconnection lines 110 may range from 50 nm to 150 nm. For example, the thickness T1 of each of the conductive interconnection lines 110 may be about 100 nm.

The conductive interconnection lines 110 and the outer pads 130 may be formed of or include at least one of metallic materials (e.g., copper). The interconnection insulating layer 120 may include at least one of a silicon oxide layer, a silicon nitride layer, a silicon oxynitride layer, or low-k dielectric layers.

Outer terminals 1000 may be provided on the bottom surface 100b of the power delivery network 100. The outer terminals 1000 may be disposed on the outer pads 130, respectively. The outer terminals 1000 may be electrically connected to the conductive interconnection lines 110. The outer terminal 1000 may be formed of an alloy containing at least one of tin (Sn), silver (Ag), copper (Cu), nickel (Ni), bismuth (Bi), indium (In), antimony (Sb), or cerium (Ce).

A first semiconductor chip 210 may be disposed on the power delivery network 100. The first semiconductor chip 210 may have a first surface 210s1 and a second surface 210s2, which are opposite to each other. The first surface 210s1 may be a top surface of the first semiconductor chip 210, and the second surface 210s2 may be a bottom surface of the first semiconductor chip 210. The second surface 210s2 of the first semiconductor chip 210 may be in direct contact with the top surface 100u of the power delivery network 100.

The first semiconductor chip 210 may include a first via 213, a first circuit layer 214, and a first chip pad 215. The first circuit layer 214 may be provided to be adjacent to the first surface 210s1 of the first semiconductor chip 210. The first circuit layer 214 may include an integrated circuit. For example, the first circuit layer 214 may include a memory circuit, a logic circuit, or combinations thereof. In other words, the first surface 210s1 of the first semiconductor chip 210 may be an active surface. The first circuit layer 214 may include an electronic device (e.g., a transistor) and an insulating pattern. The first circuit layer 214 may include a first interconnection pattern 216.

The first chip pad 215 may be disposed to be adjacent to the first surface 210s1 of the first semiconductor chip 210. The first chip pad 215 may be coupled to the first circuit layer 214 through the first interconnection pattern 216. A top surface of the first chip pad 215 may be coplanar with a top surface of the first circuit layer 214 (i.e., the first surface 210s1 of the first semiconductor chip 210). In an embodiment, a plurality of first chip pads 215 may be provided. The first chip pad 215 may be formed of or include at least one of various metallic materials (e.g., copper (Cu), aluminum (Al), and/or nickel (Ni)).

The first via 213 may be provided in the first semiconductor chip 210 to vertically extend in a second direction P2 that is perpendicular to the top surface 100u of the power delivery network 100. The first via 213 may penetrate a portion of the first semiconductor chip 210. For example, the first via 213 in the first semiconductor chip 210 may be electrically connected to the first circuit layer 214 and may extend from the first circuit layer 214 to the second surface 210s2 of the first semiconductor chip 210. The first via 213 may have the shape of circular pillar. A diameter D1 of the first via 213 may range from 0.1 μm to 5 μm. A length H1 of the first via 213 may range from 0.1 μm to 5 μm. In an embodiment, a plurality of first vias 213 may be provided. If desired, an insulating layer (not shown) may be provided to enclose the first via 213. For example, the insulating layer (not shown) may be formed of or include at least one of silicon oxide (SiO), silicon nitride (SiN), silicon oxynitride (SiON), or low-k dielectric materials.

The first via 213 may be in direct contact with a corresponding one of the conductive interconnection lines 110. The first semiconductor chip 210 may be electrically connected to the power delivery network 100 through the first via 213.

Referring to FIGS. 1, 2, and 6, a second semiconductor chip 310 may be disposed on the power delivery network 100. The second semiconductor chip 310 may be horizontally spaced apart from the first semiconductor chip 210 in a first direction P1 that is parallel to the top surface 100u of the power delivery network 100. The second semiconductor chip 310 may have a third surface 310s1 and a fourth surface 310s2, which are opposite to each other. The third surface 310s1 may be a top surface of the second semiconductor chip 310, and the fourth surface 310s2 may be a bottom surface of the second semiconductor chip 310. The fourth surface 310s2 of the second semiconductor chip 310 may be in direct contact with the top surface 100u of the power delivery network 100.

The second semiconductor chip 310 may include a second via 313, a second circuit layer 314, and a second chip pad 315. The second circuit layer 314 may be provided to be adjacent to the third surface 310s1 of the second semiconductor chip 310. The second circuit layer 314 may include an integrated circuit. For example, the second circuit layer 314 may include a logic circuit. In other words, the third surface 310s1 may be an active surface of the second semiconductor chip 310. The second circuit layer 314 may include an electronic device (e.g., a transistor) and an insulating pattern. The second circuit layer 314 may include a second interconnection pattern 316.

The second chip pad 315 may be disposed to be adjacent to the third surface 310s1 of the second semiconductor chip 310. The second chip pad 315 may be coupled to the second circuit layer 314 through the second interconnection pattern 316. A top surface of the second chip pad 315 may be coplanar with a top surface of the second circuit layer 314 (i.e., the third surface 310s1 of the second semiconductor chip 310). In an embodiment, a plurality of second chip pads 315 may be provided. The second chip pad 315 may be formed of or include at least one of various metallic materials (e.g., copper (Cu), aluminum (Al), and/or nickel (Ni)).

The second via 313 may be provided in the second semiconductor chip 310 to vertically extend in the second direction P2. The second via 313 may penetrate a portion of the first semiconductor chip 310. For example, the second via 313 in the second semiconductor chip 310 may be electrically connected to the second circuit layer 314 and may extend from the second circuit layer 314 to the fourth surface 310s2 of the second semiconductor chip 310. The second via 313 may have the shape of circular pillar. A diameter D2 of the second via 313 may range from 0.1 μm to 5 μm. A length H2 of the second via 313 may range from 0.1 μm to 5 μm. In some embodiments, a plurality of second vias 313 may be provided. If desired, an insulating layer (not shown) may be provided to enclose the second via 313. For example, the insulating layer (not shown) may be formed of or include at least one of silicon oxide (SiO), silicon nitride (SiN), silicon oxynitride (SiON), or low-k dielectric materials.

The second via 313 may be in direct contact with a corresponding one of the conductive interconnection lines 110 of the power delivery network 100. The second semiconductor chip 310 may be electrically connected to the power delivery network 100 through the second via 313.

Referring to FIGS. 1 to 4, a first chip stack CS1 may be disposed on the first semiconductor chip 210. The first chip stack CS1 may include a plurality of third semiconductor chips 220. In an embodiment, the third semiconductor chips 220 may be memory chips. Each of the third semiconductor chips 220 may include a protection layer 221, a rear pad 222, a third via 223, a third circuit layer 224, and a front pad 225. The rear pad 222 and the front pad 225 may be chip pads. The third via 223 may have a circular pillar shape. A diameter D3 of the third via 223 may range from 1 μm to 10 μm. A length H3 of the third via 223 may range from 10 μm to 50 μm.

The third semiconductor chip 220 may have a fifth surface 220s1 and a sixth surface 220s2, which are opposite to each other. The fifth surface 220s1 may be a bottom surface of the third semiconductor chip 220, and the sixth surface 220s2 may be a top surface of the third semiconductor chip 220. The fifth surface 220s1 of the third semiconductor chip 220 may be an active surface. The third semiconductor chip 220 may be provided such that the fifth surface 220s1 faces the first semiconductor chip 210. In other words, the third semiconductor chip 220 may be disposed such that the active surface thereof is placed near the first semiconductor chip 210.

The third semiconductor chips 220 may include a lower semiconductor chip 220a connected to the first semiconductor chip 210, respectively, an intermediate semiconductor chip 220b disposed on the lower semiconductor chip 220a, and an upper semiconductor chip 220c disposed on the intermediate semiconductor chip 220b. The lower semiconductor chip 220a, the intermediate semiconductor chip 220b, and the upper semiconductor chip 220c may be sequentially stacked on the first semiconductor chip 210.

The lower semiconductor chip 220a may include a first protection layer 221a, a first rear pad 222a, a lower via 223a, a lower circuit layer 224a, and a first front pad 225a. The lower circuit layer 224a may be provided to be adjacent to the bottom surface 220s1 of the lower semiconductor chip 220a. The lower circuit layer 224a may include an integrated circuit. For example, the lower circuit layer 224a may include a memory circuit. The lower circuit layer 224a may include an electronic device (e.g., a transistor) and an insulating pattern. The lower circuit layer 224a may include a lower interconnection line pattern 226a.

The lower semiconductor chip 220a may include the first protection layer 221a, which is disposed near the top surface 220s2 of the lower semiconductor chip 220a. The first protection layer 221a may be provided to be opposite to the lower circuit layer 224a. The first protection layer 221a may protect the lower semiconductor chip 220a. The first protection layer 221a may be formed of, or include, at least one of silicon oxide (SiO), silicon nitride (SiN), silicon oxynitride (SiON), or silicon carbon nitride (SiCN).

The lower via 223a may be provided in the lower semiconductor chip 220a to extend in the second direction P2. The lower via 223a may penetrate a portion of the lower semiconductor chip 220a. In an embodiment, a plurality of lower vias 223a may be provided. The lower via 223a may be electrically connected to the lower circuit layer 224a. An insulating layer (not shown) may be provided to enclose the lower via 223a. The insulating layer may be formed of or include at least one of silicon oxide (SiO), silicon nitride (SiN), silicon oxynitride (SiON), or low-k dielectric materials.

The first rear pad 222a may be disposed in the first protection layer 221a. The first protection layer 221a may be provided to expose a top surface of the first rear pad 222a. A top surface of the first protection layer 221a (i.e., the top surface 220s2 of the lower semiconductor chip 220a) may be coplanar with the top surface of the first rear pad 222a. The first rear pad 222a may be connected to the lower via 223a. The first front pad 225a may be disposed to be adjacent to the bottom surface 220s1 of the lower semiconductor chip 220a. The first front pad 225a may be exposed to the outside of the lower semiconductor chip 220a near the bottom surface 220s1. A bottom surface of the first front pad 225a may be coplanar with a bottom surface of the lower circuit layer 224a (i.e., the bottom surface 220s1 of the lower semiconductor chip 220a). The first front pad 225a may be coupled to the lower circuit layer 224a. The lower interconnection line pattern 226a in the lower circuit layer 224a may be coupled to the first front pad 225a. The first rear pad 222a and the first front pad 225a may be electrically connected to each other through the lower circuit layer 224a and the lower via 223a. In an embodiment, a plurality of first rear pads 222a and a plurality of first front pads 225a may be provided. The first rear pad 222a and the first front pad 225a may be formed of or include at least one of various metallic materials (e.g., copper (Cu), aluminum (Al), and/or nickel (Ni)).

Referring to FIG. 4, the lower semiconductor chip 220a may be mounted on the first semiconductor chip 210. In detail, the lower semiconductor chip 220a may be disposed on the first semiconductor chip 210. The lower semiconductor chip 220a may be disposed on the first semiconductor chip 210 in a face-down manner. The first chip pad 215 of the first semiconductor chip 210 and the first front pad 225a of the lower semiconductor chip 220a may be vertically aligned to each other in the second direction P2. The first semiconductor chip 210 and the lower semiconductor chip 220a may be in contact with each other, connecting the first chip pad 215 and the first front pad 225a to each other. For example, the first semiconductor chip 210 and the lower semiconductor chip 220a may be bonded to each other in a face-to-face manner.

The lower semiconductor chip 220a may be electrically connected to the first semiconductor chip 210. In detail, the lower semiconductor chip 220a and the first semiconductor chip 210 may be in contact with each other. At an interface between the lower semiconductor chip 220a and the first semiconductor chip 210, the first chip pad 215 of the first semiconductor chip 210 may be bonded to the first front pad 225a of the lower semiconductor chip 220a. Here, the first chip pad 215 and the first front pad 225a may form an inter-metal hybrid bonding structure. In the present specification, the term “hybrid bonding structure” may refer to a bonding structure that is formed by two materials that are of the same kind and that are fused at an interface therebetween. For example, the first chip pad 215 and the first front pad 225a, which are bonded to each other, may have a continuous structure such that there may be no observable interface between the first chip pad 215 and the first front pad 225a. For example, the first chip pad 215 and the first front pad 225a may be formed of the same material and may be in contact with each other without an interface therebetween. In other words, the first chip pad 215 and the first front pad 225a may be provided as a single element. In other words, the first chip pad 215 and the first front pad 225a may be bonded to form a single object.

At the interface between the first semiconductor chip 210 and the lower semiconductor chip 220a, the insulating pattern of the first circuit layer 214 of the first semiconductor chip 210 may be bonded to the insulating pattern of the lower circuit layer 224a of the lower semiconductor chip 220a. Here, the insulating pattern of the first circuit layer 214 and the insulating pattern of the lower circuit layer 224a may form a hybrid bonding structure of oxide, nitride, or oxynitride. For example, the insulating pattern of the first circuit layer 214 and the insulating pattern of the lower circuit layer 224a may be formed of the same material and may be in contact with each other without an interface therebetween. In other words, the insulating pattern of the first circuit layer 214 and the insulating pattern of the lower circuit layer 224a may be bonded to form a single object as a non-limiting example. The insulating pattern of the first circuit layer 214 and the insulating pattern of the lower circuit layer 224a may be formed of different materials from each other and may not have a continuous structure. In this case, there might be an observable interface between the insulating pattern of the first circuit layer 214 and the insulating pattern of the lower circuit layer 224a.

The intermediate semiconductor chip 220b may have substantially the same structure as the lower semiconductor chip 220a. For example, the intermediate semiconductor chip 220b may include an intermediate circuit layer 224b adjacent to the bottom surface 220s1 of the intermediate semiconductor chip 220b, a second protection layer 221b adjacent to the top surface 220s2 of the intermediate semiconductor chip 220b, an intermediate via 223b penetrating the intermediate semiconductor chip 220b in the second direction P2, a second rear pad 222b in the second protection layer 221b, and a second front pad 225b adjacent to the bottom surface 220s1 of the intermediate semiconductor chip 220b. The intermediate circuit layer 224b and the second front pad 225b may be provided to be adjacent to the bottom surface 220s1 of the intermediate semiconductor chip 220b, and the bottom surface of the intermediate semiconductor chip 220b may be an active surface. The second protection layer 221b and the second rear pad 222b may be provided to be adjacent to the top surface 220s2 of the intermediate semiconductor chip 220b. In an embodiment, a plurality of intermediate semiconductor chips 220b may be provided. For example, the intermediate semiconductor chips 220b may be stacked between the lower semiconductor chip 220a and the upper semiconductor chip 220c.

The intermediate semiconductor chip 220b may be mounted on the lower semiconductor chip 220a. In detail, the intermediate semiconductor chip 220b may be disposed on the lower semiconductor chip 220a. The intermediate semiconductor chip 220b may be disposed on the lower semiconductor chip 220a in a face-down manner. The first rear pad 222a of the lower semiconductor chip 220a may be aligned to the second front pad 225b of the intermediate semiconductor chip 220b in the second direction P2. The lower semiconductor chip 220a and the intermediate semiconductor chip 220b may be in contact with each other, connecting the first rear pad 222a and the second front pad 225b to each other.

The intermediate semiconductor chip 220b may be connected to the lower semiconductor chip 220a. In detail, the intermediate semiconductor chip 220b and the lower semiconductor chip 220a may be in contact with each other. At an interface between the intermediate semiconductor chip 220b and the lower semiconductor chip 220a, the first rear pad 222a of the lower semiconductor chip 220a may be bonded to the second front pad 225b of the intermediate semiconductor chip 220b. Here, the first rear pad 222a and the second front pad 225b may form an inter-metal hybrid bonding structure. For example, the first rear pad 222a and the second front pad 225b, which are bonded to each other, may have a continuous structure, and there may be no observable interface between the first rear pad 222a and the second front pad 225b. For example, the first rear pad 222a and the second front pad 225b may be formed of the same material and may be in contact with each other without an interface therebetween. In other words, the first rear pad 222a and the second front pad 225b may be provided as a single element. For example, the first rear pad 222a and the second front pad 225b may be bonded to form a single object.

At the interface between the intermediate semiconductor chip 220b and the lower semiconductor chip 220a, the first protection layer 221a of the lower semiconductor chip 220a may be bonded to the insulating pattern of the intermediate circuit layer 224b of the intermediate semiconductor chip 220b. Here, the first protection layer 221a and the insulating pattern of the intermediate circuit layer 224b may form a hybrid bonding structure of oxide, nitride, oxynitride, or carbon nitride. For example, the first protection layer 221a and the insulating pattern of the intermediate circuit layer 224b may be formed of the same material (e.g., silicon oxide (SiO), silicon nitride (SiN), silicon oxynitride (SiON), or silicon carbon nitride (SiCN)) and may be in contact with each other without an interface therebetween. In other words, the first protection layer 221a and the insulating pattern of the intermediate circuit layer 224b may be bonded to form a single object, as a non-limiting example. The first protection layer 221a and the insulating pattern of the intermediate circuit layer 224b may be formed of different materials from each other and may might not have a continuous structure. In this case, there may be an observable interface between the first protection layer 221a and the insulating pattern of the intermediate circuit layer 224b.

The upper semiconductor chip 220c may have substantially the same structure as the lower semiconductor chip 220a. For example, the upper semiconductor chip 220c may include an upper circuit layer 224c which is adjacent to the bottom surface 220s1 of the upper semiconductor chip 220c, a third protection layer 221c, which is adjacent to the top surface 220s2 of the upper semiconductor chip 220c, an upper via 223c, which extends in the second direction P2, a third rear pad 222c, which is placed in the third protection layer 221c, and a third front pad 225c, which is adjacent to the bottom surface 220s1 of the upper semiconductor chip 220c. The upper circuit layer 224c and the third front pad 225c may be provided near a bottom surface of the upper semiconductor chip 220c, and the bottom surface of the upper semiconductor chip 220c may be an active surface. The third protection layer 221c and the third rear pad 222c may be provided near a top surface of the upper semiconductor chip 220c.

The upper semiconductor chip 220c may be mounted on the intermediate semiconductor chip 220b. In detail, the upper semiconductor chip 220c may be disposed on the intermediate semiconductor chip 220b. The upper semiconductor chip 220c may be disposed on the intermediate semiconductor chip 220b in a face-down manner. The second rear pad 222b of the intermediate semiconductor chip 220b and the third front pad 225c of the upper semiconductor chip 220c may be aligned to each other in the second direction P2. The upper semiconductor chip 220c and the intermediate semiconductor chip 220b may be in contact with each other, connecting the second rear pad 222b and the third front pad 225c to each other.

The upper semiconductor chip 220c may be connected to the intermediate semiconductor chip 220b. In detail, the upper semiconductor chip 220c and the intermediate semiconductor chip 220b may be in contact with each other. At an interface between the upper semiconductor chip 220c and the intermediate semiconductor chip 220b, the second rear pad 222b of the intermediate semiconductor chip 220b may be bonded to the third front pad 225c of the upper semiconductor chip 220c. Here, the second rear pad 222b and the third front pad 225c may form an inter-metal hybrid bonding structure. For example, the second rear pad 222b and the third front pad 225c, which are bonded to each other, may have a continuous structure, and there may be no observable interface between the second rear pad 222b and the third front pad 225c. For example, the second rear pad 222b and the third front pad 225c may be formed of the same material and may be in contact with each other without an interface therebetween. In other words, the second rear pad 222b and the third front pad 225c may be provided as a single element. For example, the second rear pad 222b and the third front pad 225c may be bonded to form a single object.

At the interface between the upper semiconductor chip 220c and the intermediate semiconductor chip 220b, the second protection layer 221b of the intermediate semiconductor chip 220b may be bonded to the insulating pattern of the upper circuit layer 224c of the upper semiconductor chip 220c. Here, the second protection layer 221b and the insulating pattern of the upper circuit layer 224c may form a hybrid bonding structure of oxide, nitride, oxynitride, or carbon nitride. For example, the second protection layer 221b and the insulating pattern of the upper circuit layer 224c may be formed of the same material (e.g., silicon oxide (SiO), silicon nitride (SiN), silicon oxynitride (SiON), or silicon carbon nitride (SiCN)) and may be in contact with each other without an interface therebetween. In other words, the second protection layer 221b and the insulating pattern of the upper circuit layer 224c may be bonded to form a single object, as a non-limiting example. The second protection layer 221b and the insulating pattern of the upper circuit layer 224c may be formed of different materials from each other and may not have a continuous structure. In this case, there may be an observable interface between the second protection layer 221b and the insulating pattern of the upper circuit layer 224c.

The lower semiconductor chip 220a, the intermediate semiconductor chip 220b, and the upper semiconductor chip 220c may be bonded to form the first chip stack CS1. When the third semiconductor chips 220 of the first chip stack CS1 are bonded to each other through the hybrid bonding structure, adjacent ones of the third semiconductor chips 220 may be in direct contact with each other.

The second semiconductor chip 310 and the first chip stack CS1 may be electrically connected to each other through the power delivery network 100. For example, the second semiconductor chip 310 may be electrically connected to the third semiconductor chips 220 through the power delivery network 100.

A second chip stack CS2 may be disposed on the second semiconductor chip 310. The second chip stack CS2 may include a fourth semiconductor chip 320. For example, the fourth semiconductor chip 320 may be a dummy chip. In an embodiment, the fourth semiconductor chip 320 may be formed of or include silicon (Si). The second chip stack CS2 may further include a first adhesive layer 330 between the second semiconductor chip 310 and the fourth semiconductor chip 320. In an embodiment, the first adhesive layer 330 may be formed of or include silicon oxide. In an embodiment, a plurality of fourth semiconductor chips 320 may be provided. In this case, the first adhesive layer 330 may be further provided between the fourth semiconductor chips 320. The uppermost surface of the fourth semiconductor chip 320 may be located at substantially the same height as the top surface of the upper semiconductor chip 220c. In other words, a top surface of the first chip stack CS1 and a top surface of the second chip stack CS2 may be located at substantially the same height.

An upper silicon substrate 400 may be further provided on the first chip stack CS1 and the second chip stack CS2. The upper silicon substrate 400 may be, for example, a silicon wafer. As an example, the upper silicon substrate 400 may be a dummy silicon wafer. The upper silicon substrate 400 may be vertically aligned to the power delivery network 100 in the second direction P2. A second adhesive layer 410 may be further provided between the upper silicon substrate 400 and the first chip stack CS1 and the second chip stack CS2. For example, the second adhesive layer 410 may be formed of or include silicon oxide.

A mold layer 500 may be further provided between the upper silicon substrate 400 and the power delivery network 100. The mold layer 500 may fill spaces between the second adhesive layer 410 and the power delivery network 100, between the first chip stack CS1 and the second chip stack CS2, and between the first and second semiconductor chips 210 and 310. The mold layer 500 may be formed of or include an insulating material. For example, the mold layer 500 may be formed of or include an epoxy molding compound (EMC).

According to an embodiment, the semiconductor package may include the power delivery network 100 provided on the first and second semiconductor chips 210 and 310. The second semiconductor chip 310 may be electrically connected to the third semiconductor chips 220 through the power delivery network 100. With the power delivery network 100, it may be possible to facilitate data transmission between the second semiconductor chip 310 and the third semiconductor chips 220, as well as supply power to both the second and third semiconductor chips 310 and 220. Accordingly, it may be possible to provide a semiconductor package with improved performance.

In addition, by disposing the second chip stack CS2 on the second semiconductor chip 310 and disposing the upper silicon substrate 400 on the first and second chip stacks CS1 and CS2, it may be possible to easily exhaust heat that may be generated from the semiconductor chips. Thus, it may be possible to provide a semiconductor package with improved stability.

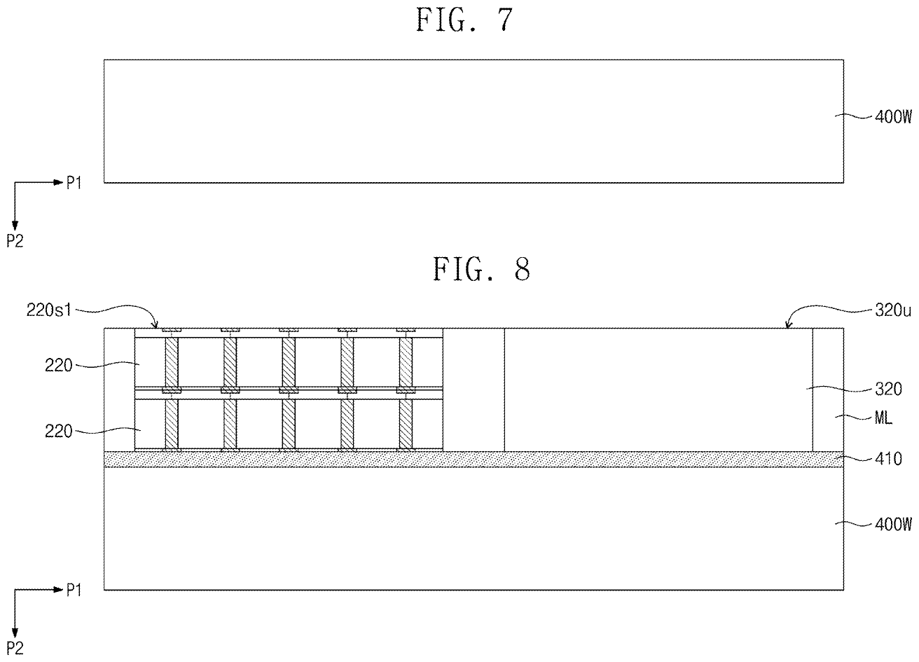

FIGS. 7 to 12 are sectional views that are taken along the line I-I′ of FIG. 1 to illustrate a method of fabricating a semiconductor package, according to an embodiment.

Referring to FIG. 7, a substrate 400W may be provided. The substrate 400W may be a carrier substrate. As an example, the substrate 400W may be a silicon wafer.

Referring to FIG. 8, the second adhesive layer 410 may be provided on the substrate 400W. The third semiconductor chip 220 and the fourth semiconductor chip 320 may be provided on the second adhesive layer 410. The third semiconductor chip 220 may be disposed such that the fifth surface 220s1 is positioned on an opposite side of the substrate 400W. For example, the third semiconductor chip 220 may be disposed such the active surface 220s1 is placed in an opposite direction of the second direction P2. The fourth semiconductor chip 320 may be disposed such that a top surface 320u thereof is located at substantially the same height as the sixth surface 220s2 of the third semiconductor chip 220. The third semiconductor chip 220 and the fourth semiconductor chip 320 may be attached to the substrate 400W through an oxide bonding structure.

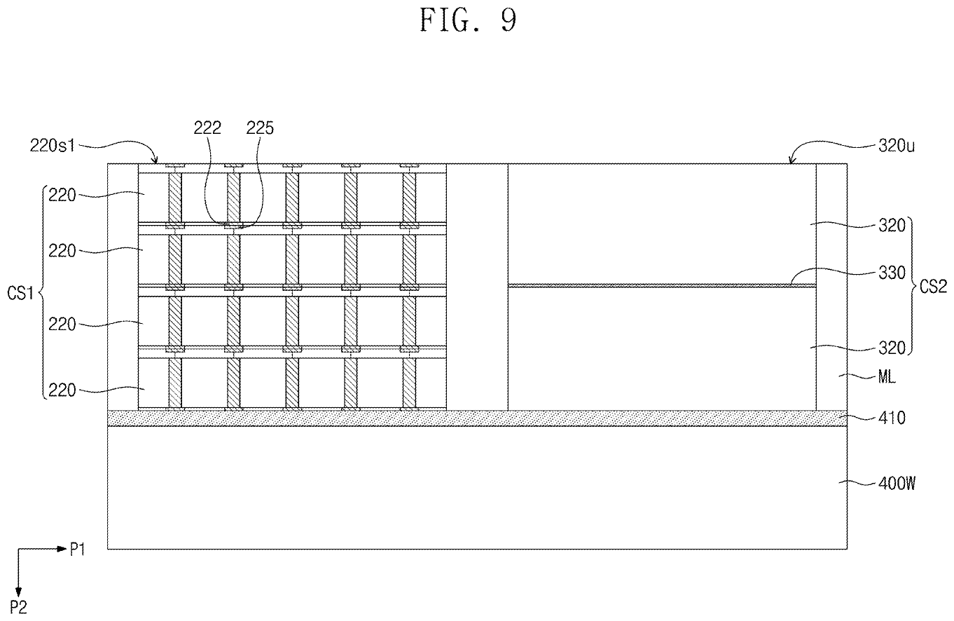

Referring to FIG. 9, the first chip stack CS1 and the second chip stack CS2 may be formed on the substrate 400W. The first chip stack CS1 may be formed by bonding the third semiconductor chips 220 to each other. Each of the third semiconductor chips 220 may be disposed such that the rear pad 222 and the front pad 225 are located near its bottom and top surfaces, respectively. The third semiconductor chips 220 may be vertically aligned with each other, and then, a thermal treatment process may be performed on the third semiconductor chips 220. As a result of the thermal treatment process, the front and rear pads 225 and 222 in adjacent ones of the third semiconductor chips 220 may form a single object that is formed of the same metallic material (e.g., copper (Cu)). The front and rear pads 225 and 222, which are in contact with each other, may be bonded to each other through an inter-metal hybrid bonding structure. The top surface 220s1 of the first chip stack CS1 and the top surface 320u of the second chip stack CS2 may be located at substantially the same height.

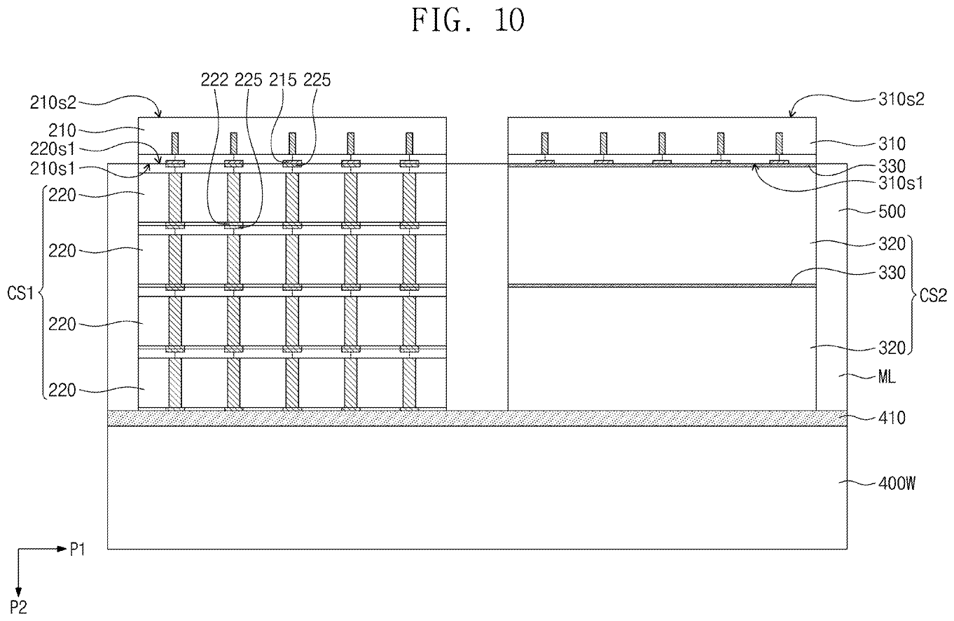

Referring to FIG. 10, the first semiconductor chip 210 may be bonded to the first chip stack CS1, and the second semiconductor chip 310 may be bonded to the second chip stack CS2. The bonding of the first semiconductor chip 210 may be performed such that the first surface 210s1 faces the first chip stack CS1. In other words, the bonding of the first semiconductor chip 210 may be performed such that its active surface faces the first chip stack CS1. Thus, the active surface of the first semiconductor chip 210 may be in contact with the first chip stack CS1.

The first semiconductor chip 210 may be aligned to the first chip stack CS1 in the second direction P2 (e.g., vertically), and then, a thermal treatment process may be performed on the first semiconductor chip 210. As a result of the thermal treatment process, the first chip pad 215 of the first semiconductor chip 210 and the front pad 225 of the third semiconductor chip 220 may form a single object that is formed of the same metallic material (e.g., copper (Cu)). The first chip pad 215 and the front pad 225, which are in contact with each other, may be bonded to each other through an inter-metal hybrid bonding structure.

The second semiconductor chip 310 may be aligned to the fourth semiconductor chip 320 in the second direction P2 (e.g., vertically). Then, an oxide bonding process may be performed to attach the second semiconductor chip 310 to the fourth semiconductor chip 320. This process may be performed when the third surface 310s1 of the second semiconductor chip 310 is placed to face the second chip stack CS2. For example, the second semiconductor chip 310 may be bonded to the fourth semiconductor chip 320 such that its active surface faces the second chip stack CS2. Thus, the active surface of the second semiconductor chip 310 may be in contact with the second chip stack CS2.

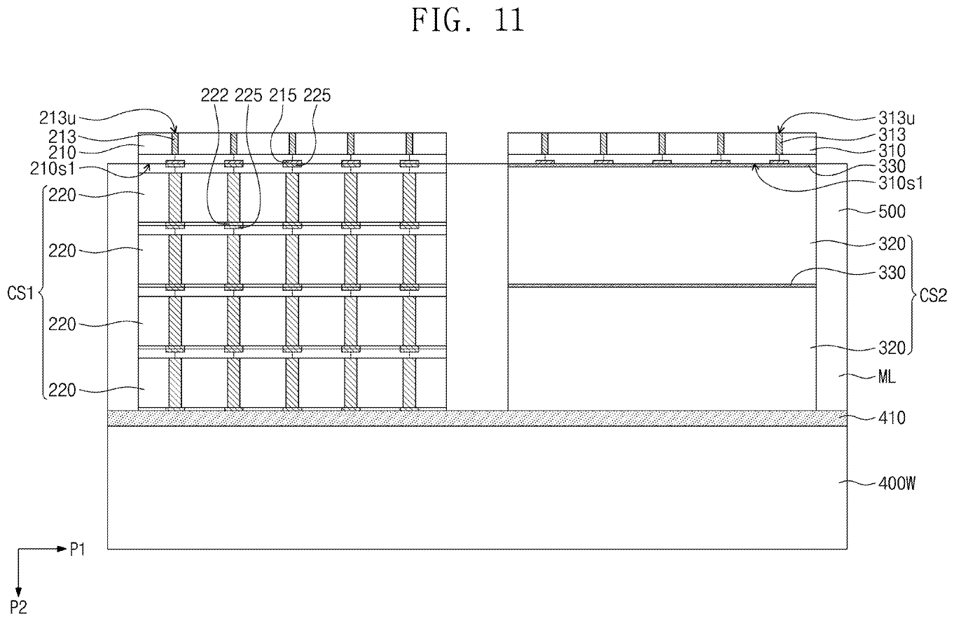

Referring to FIG. 11, the first and second semiconductor chips 210 and 310 may be polished to expose a top surface 213u of the first via 213 and a top surface 313u of the second via 313.

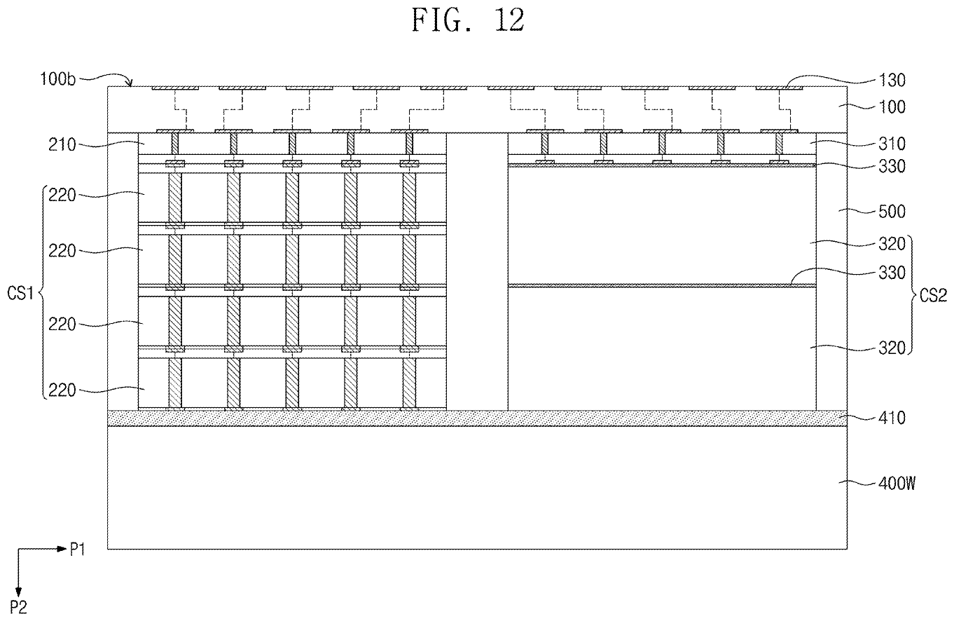

Referring to FIG. 12, the power delivery network 100 may be formed on the first and second semiconductor chips 210 and 310. The power delivery network 100 may be formed by a back-end-of-line (BEOL) process. The power delivery network 100 may include the conductive interconnection lines 110, which are connected to the first via 213 and the second via 313. The outer pads 130 may be formed to be connected to corresponding ones of the conductive interconnection lines 110. The interconnection insulating layer 120 may be formed to cover the conductive interconnection lines 110. The interconnection insulating layer 120 may be formed to expose top surfaces of the outer pads 130.

Referring back to FIG. 1, the outer terminals 1000 may be formed on the outer pads 130. The upper silicon substrate 400 may be formed by grinding the substrate 400W. As a result, the semiconductor package may be fabricated.

According to an embodiment, a semiconductor package may include a power delivery network that is provided on first and second semiconductor chips. With the power delivery network, it may be possible to facilitate data transmission between second and third semiconductor chips and to easily supply power to both the second and third semiconductor chips. Accordingly, it may be possible to provide a semiconductor package with improved performance.

In the semiconductor package, by disposing a second chip stack on the second semiconductor chip and disposing an upper silicon substrate on first and second chip stacks, it may be possible to easily exhaust heat that is generated from the semiconductor chips. Thus, it may be possible to provide a semiconductor package with improved stability.

While example embodiments have been particularly shown and described, it is to be understood by one of ordinary skill in the art that variations in form and detail may be made therein without departing from the spirit and scope of the attached claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a power delivery network;
a first semiconductor chip disposed on a top surface of the power delivery network, the first semiconductor chip having a first surface and a second surface that are opposite to each other;
a second semiconductor chip disposed on the top surface of the power delivery network and horizontally spaced apart from the first semiconductor chip, the second semiconductor chip having a third surface and a fourth surface that are opposite to each other;
a first chip stack disposed on the first surface of the first semiconductor chip; and
a second chip stack disposed on the third surface of the second semiconductor chip,
wherein:
the first surface of the first semiconductor chip is an active surface of the first semiconductor chip,
the third surface of the second semiconductor chip is an active surface of the second semiconductor chip,
the first chip stack includes third semiconductor chips stacked on the first surface of the first semiconductor chip,
each of the third semiconductor chips is disposed such that an active surface thereof faces the first semiconductor chip, and
the first chip stack and the second semiconductor chip are electrically connected to each other through the power delivery network.

2. The semiconductor package as claimed in claim 1, further comprising an upper silicon substrate on the first chip stack and the second chip stack.

3. The semiconductor package as claimed in claim 1, wherein the top surface of the power delivery network is in direct contact with the second surface of the first semiconductor chip and the fourth surface of the second semiconductor chip.

4. The semiconductor package as claimed in claim 1, wherein:
the first semiconductor chip includes a first chip pad adjacent to the first surface,
each of the third semiconductor chips includes a second chip pad adjacent to a bottom surface of each of the third semiconductor chips, and
the first chip pad of the first semiconductor chip and the second chip pad of a lowermost one of the third semiconductor chips are bonded to each other.

5. The semiconductor package as claimed in claim 4, wherein the first chip pad and the second chip pad form a single object that is formed of the same metallic material.

6. The semiconductor package as claimed in claim 1, wherein adjacent ones of the third semiconductor chips are in direct contact with each other.

7. The semiconductor package as claimed in claim 1, wherein:
the first semiconductor chip includes a first via penetrating a portion of the first semiconductor chip,
the second semiconductor chip includes a second via penetrating a portion of the second semiconductor chip,
each of the third semiconductor chips includes a third via penetrating a portion of each of the third semiconductor chips, and
a diameter of the third via is larger than each of a diameter of the first via and a diameter of the second via.

8. The semiconductor package as claimed in claim 7, wherein a length of the third via is larger than a length of the first via and a length of the second via.

9. The semiconductor package as claimed in claim 8, wherein the power delivery network includes conductive interconnection lines and an interconnection insulating layer, and
each of the first and second vias is in direct contact with a corresponding one of the conductive interconnection lines.

10. The semiconductor package as claimed in claim 1, wherein the power delivery network includes conductive interconnection lines and an interconnection insulating layer.

11. The semiconductor package as claimed in claim 10, wherein the conductive interconnection lines include a metallic material, and
the interconnection insulating layer includes at least one of a silicon oxide layer, a silicon nitride layer, a silicon oxynitride layer, or low-k dielectric layers.

12. The semiconductor package as claimed in claim 1, wherein the power delivery network further includes outer terminals on a bottom surface of the power delivery network.

13. A semiconductor package, comprising:
a first semiconductor chip having a first surface and a second surface, which are opposite to each other, the first surface being an active surface of the first semiconductor chip;
a second semiconductor chip horizontally spaced apart from the first semiconductor chip, the second semiconductor chip having a third surface and a fourth surface, which are opposite to each other, the third surface being an active surface of the second semiconductor chip;
a power delivery network in direct contact with the second surface of the first semiconductor chip and the fourth surface of the second semiconductor chip;
third semiconductor chips vertically stacked on the first surface of the first semiconductor chip;
dummy chips disposed on the third surface of the second semiconductor chip; and
a silicon substrate disposed on the third semiconductor chips and the dummy chips,
wherein:
the first semiconductor chip includes a first via penetrating a portion of the first semiconductor chip,
the second semiconductor chip includes a second via penetrating a portion of the second semiconductor chip,
the power delivery network includes conductive interconnection lines and an interconnection insulating layer,
each of the first and second vias is in direct contact with a corresponding one of the conductive interconnection lines,
each of the third semiconductor chips is disposed such that an active surface of each of the third semiconductor chips faces the first semiconductor chip, and
the third semiconductor chips are electrically connected to the second semiconductor chip through the power delivery network.

14. The semiconductor package as claimed in claim 13, wherein:
each of the third semiconductor chips includes a third via penetrating a portion of each of the third semiconductor chips, and
a diameter of the third via is larger than a diameter of the first via and a diameter of the second via.

15. The semiconductor package as claimed in claim 13, wherein each of the third semiconductor chips is in direct contact with others of the third semiconductor chips adjacent thereto.

16. A method of fabricating a semiconductor package, comprising:
preparing a silicon substrate;
forming a first chip stack and a second chip stack on the silicon substrate;
bonding a first semiconductor chip to the first chip stack;
bonding a second semiconductor chip to the second chip stack; and
forming a power delivery network on the first and second semiconductor chips,
wherein:
the first chip stack includes third semiconductor chips,
a top surface of each of the third semiconductor chips is an active surface,
an active surface of the first semiconductor chip is in contact with the first chip stack,
an active surface of the second semiconductor chip is in contact with the second chip stack, and
the third semiconductor chips are electrically connected to the second semiconductor chip through the power delivery network.

17. The method as claimed in claim 16, wherein:
the first and second semiconductor chips include penetration vias, respectively, and
the method further includes a polishing step to expose top surfaces of the penetration vias before the forming of the power delivery network.

18. The method as claimed in claim 16, further comprising:
forming outer terminals on the power delivery network, after the forming of the power delivery network; and
polishing the silicon substrate.

19. The method as claimed in claim 16, wherein the forming of the first chip stack includes:
providing the third semiconductor chips, each of which includes a first chip pad and a second chip pad; and
performing a thermal treatment process on the third semiconductor chips to bond the third semiconductor chips to each other,
wherein:
the first chip pad is disposed to be adjacent to a bottom surface of each of the third semiconductor chips,
the second chip pad is disposed to be adjacent to the top surface of each of the third semiconductor chips, and
the thermal treatment process is performed such that the first and second chip pads form a single object formed of the same metallic material.

20. The method as claimed in claim 19, wherein the metallic material includes copper (Cu).
